(19) United States
(12) Patent Application Publication
(10) Pub. No.: US 2013/0214332 A1
(43) Pub. Date: Aug. 22, 2013

(54) NANOGRID CHANNEL FIN-FET TRANSISTOR AND BIOSENSOR

(71) Applicant: Qiang Wu, Plano, TX (US)

(72) Inventor: Qiang Wu, Plano, TX (US)

(73) Assignee: Diagtronix, Inc., Carrollton, TX (US)

(21) Appl. No.: 13/590,597

(22) Filed: Aug. 21, 2012

Related U.S. Application Data
(60) Provisional application No. 61/527,647, filed on Aug. 26, 2011.

(51) Int. Cl. H01L 29/06; H01L 29/66; G01N 27/414

(52) U.S. Cl. CPC H01L 29/0665; G01N 27/414; H01L 29/66795
USPC 257/253; 438/49

(57) ABSTRACT

A transistor includes a source region, a drain region, and a nanogrid channel connecting the source and drain regions. The nanogrid channel includes first and second vertical channel regions connecting the source and drain regions. The first and second vertical channel regions have a space therebetween. A cross member extends from the first vertical channel region into the space.

### CROSS REFERENCE TO RELATED APPLICATIONS

This application claims the benefit of U.S. Provisional Patent Application No. 61/527,647 filed on Aug. 26, 2011 and incorporated herein by reference.

### TECHNICAL FIELD

The present invention relates generally to transistors, and more particularly to fin-FET or MuG-FET transistors.

### BACKGROUND

Fin-FET transistors employ a vertical channel, or fin, connecting a source and drain. Unlike planar transistors, a gate electrode may contact the channel of the fin-FET transistor on multiple sides. Hence, the fin-FET is sometime also referred to as a MuG (multi-gate) FET. A fin-FET may have one or a plurality of vertical channels.

The exposure of the vertical channel makes the fin-FET an attractive candidate for various sensing applications. Some types of sensors have been demonstrated using fin-FET devices. While such sensors show great promise, continued improvement is needed to make such devices available in a wide variety of applications.

### SUMMARY

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

One aspect provides a transistor, e.g. a fin-FET or MuGFET transistor. The transistor includes a source region, a drain region, and a nanogrid channel connecting the source and drain regions. The nanogrid channel includes first and second vertical channel regions connecting the source and drain regions. The first and second vertical channel regions have a space therebetween. A cross member extends from the first vertical channel region into the space.

Another aspect provides a method, e.g. for forming a transistor. The method includes forming a source region and a drain region over a substrate, and forming a nanogrid channel connecting the source and drain regions. The nanogrid channel includes first and second vertical channel regions connecting the source and drain regions and having a space therebetween. A cross member extends from the first vertical channel region into the space.

In some of the above-described embodiments the cross member physically connects the first and second vertical channel regions. In some such embodiments the cross member may include a low conductivity region that reduces conduction between the first and second vertical channel regions through the cross member. In other embodiments the cross member may include two PN junctions that share a common n-doped region or a common p-doped region, thereby substantially preventing conduction between the first and second vertical channel regions through the cross member.

In some embodiments an oxide layer, e.g. silicon oxide, underlies the first and second vertical channel regions. In some such embodiments a portion of the oxide layer may be removed from under the first and second channel regions.

In some embodiments a sensitizing layer is located on the nanogrid channel. The sensitizing layer is configured to interact with a target molecular species in contact with the nanogrid channel thereby changing an electrical parameter of the transistor.

In some embodiments the transistor includes a dielectric overlying the nanogrid channel. A sample channel may be located within the dielectric and may expose a portion of the nanogrid channel.

### BRIEF DESCRIPTION

Embodiments of the present invention are described with reference to the attached figures. It should be understood that numerous specific details, relationships, and methods are set forth to provide an understanding of the various embodiments. Those skilled in the pertinent art will, however, recognize that other embodiments can be practiced without one or more of the disclosed features, with some other features, or by methods that differ from the disclosed methods. In some instances, well-known structures or operations are not shown in detail to avoid obscuring other relevant features of the described embodiment.

Reference is now made to the following descriptions taken in conjunction with the accompanying drawings, in which like reference numerals are used throughout the figures to designate similar or equivalent elements. The figures may not be drawn to scale and illustrate nonlimiting embodiments of the invention.

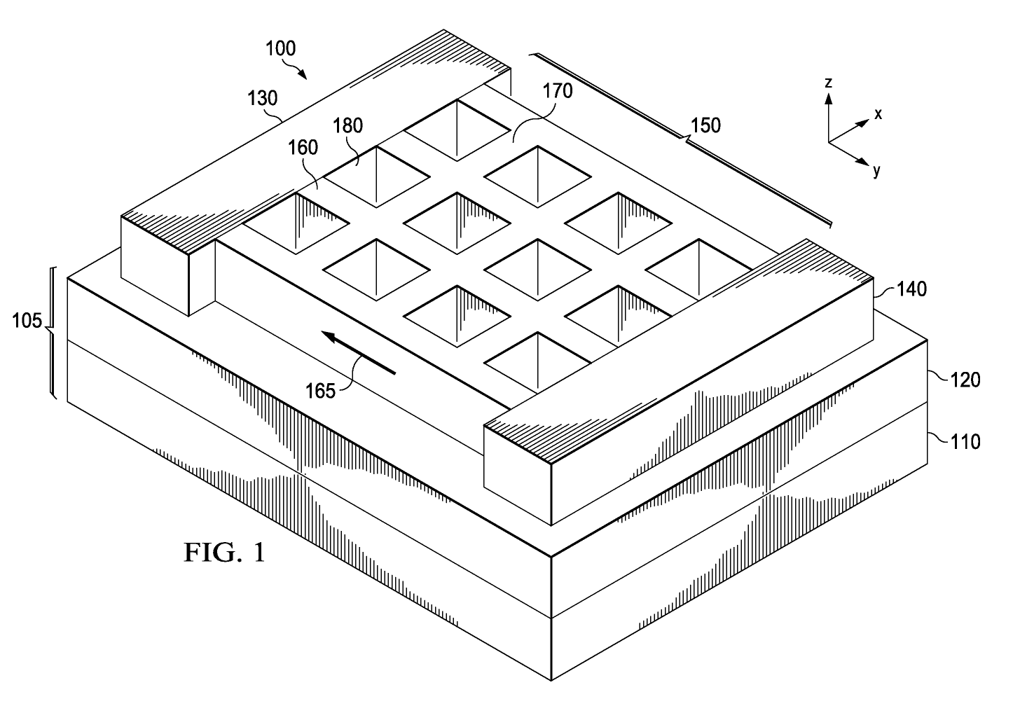

FIG. 1 illustrates a nanogrid fin-FET according to one embodiment of the invention, in which multiple semiconducting vertical channels connect a source and a drain, and semiconducting segments connect neighboring fins;

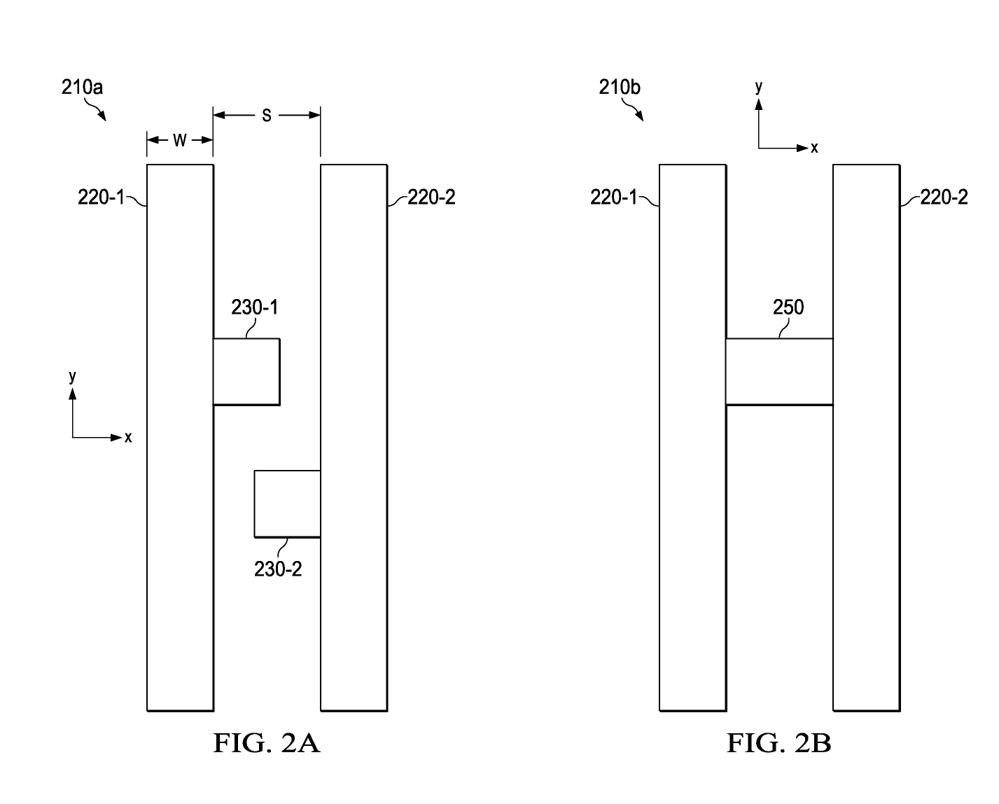

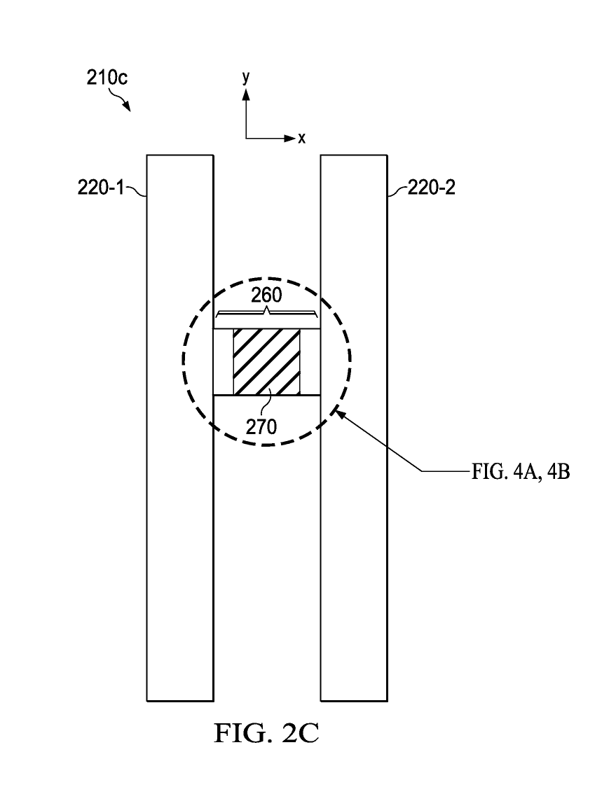

FIG. 2A illustrates two vertical channel segments according to one embodiment, in which orthogonal channel segments extend only partially to the neighboring channel;

FIG. 2B illustrates two vertical channel segments according to one embodiment, in which an orthogonal channel segment extends fully between the two channel segments;

FIG. 2C illustrates the channel segments of FIG. 2B, in which a blocking element reduces conduction between the two vertical channel segments;

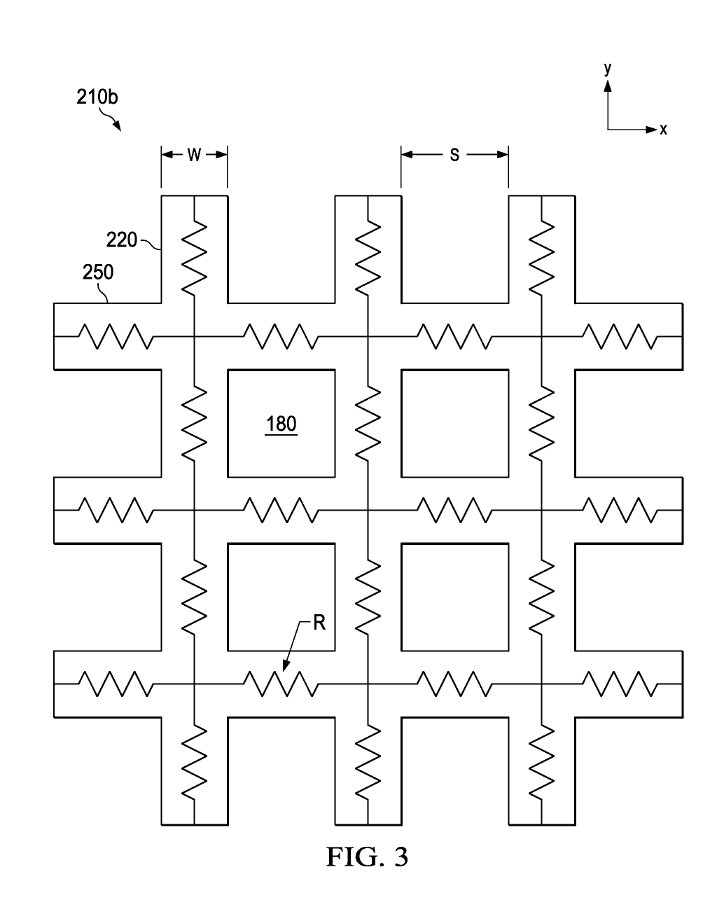

FIG. 3 illustrates a regular array of channel segments according to one embodiment, including an electrical equivalent circuit of the array, e.g. a resistor ladder;

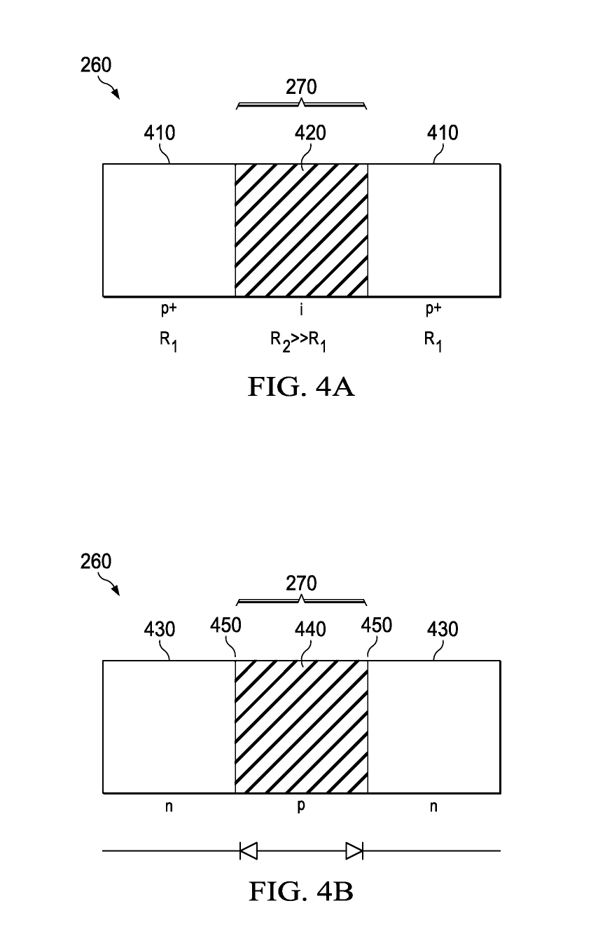

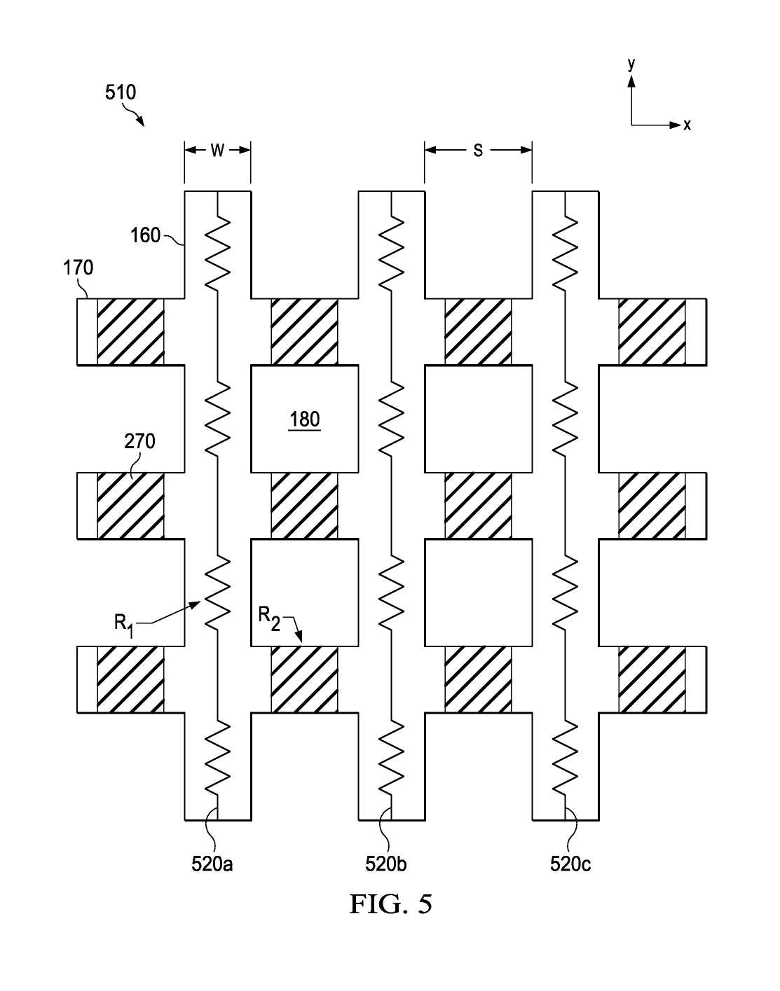

FIGS. 4A and 4B illustrate aspects of embodiments of the blocking element of FIG. 2C, e.g. a resistive blocking element in FIG. 4A and a junction blocking element in FIG. 4B;

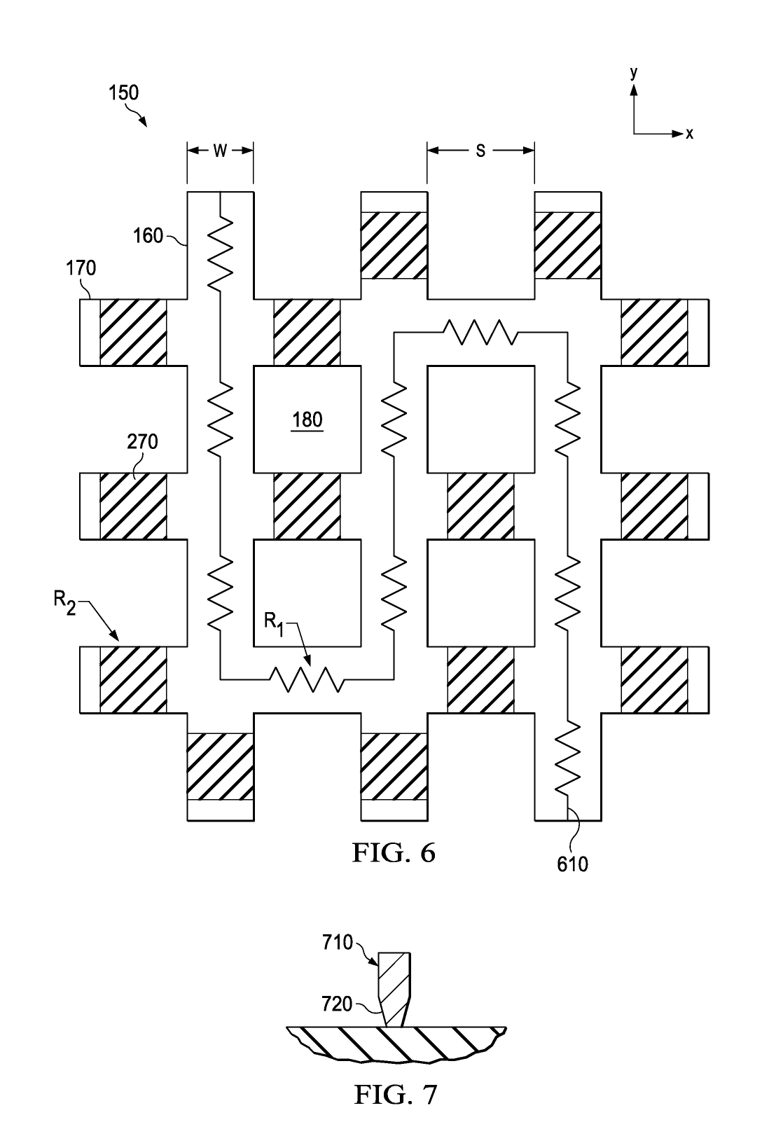

FIG. 5 illustrates the regular array of channel segments of FIG. 3, including multiple instances of the blocking element of FIG. 2C, in which the blocking elements configure the array to have multiple parallel conduction paths;

FIG. 6 illustrates the regular array of channel segments of FIG. 3, including multiple instances of the blocking element of FIG. 2C, in which the blocking elements configure the array to have a serpentine conduction path;

FIG. 7 illustrates a sectional view of a vertical channel that includes an undercut;

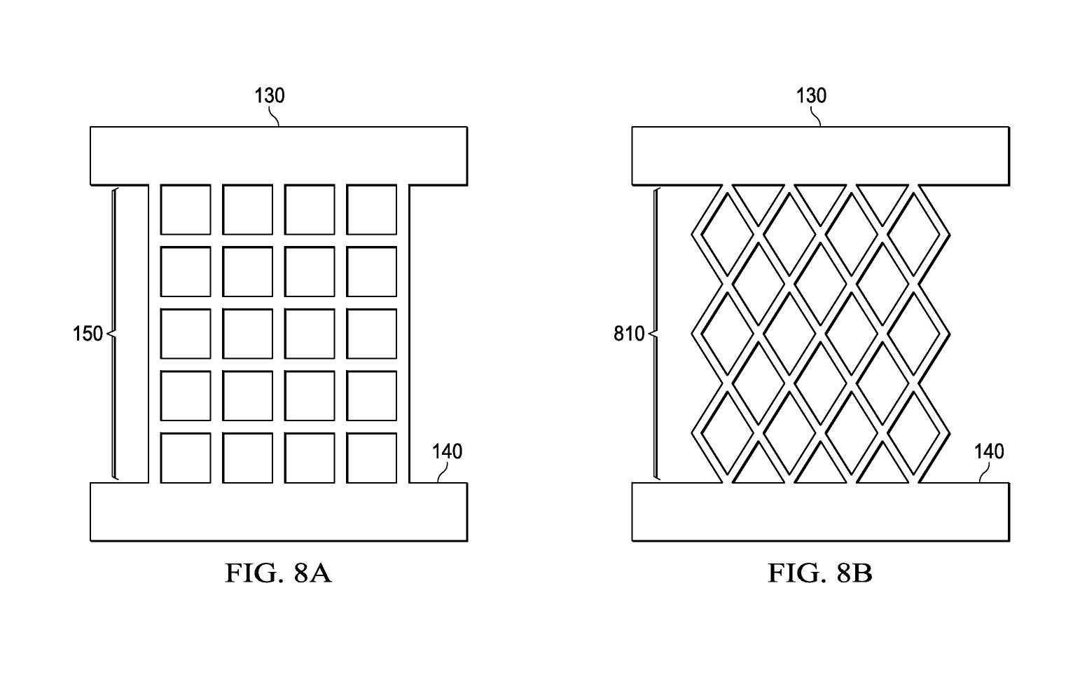

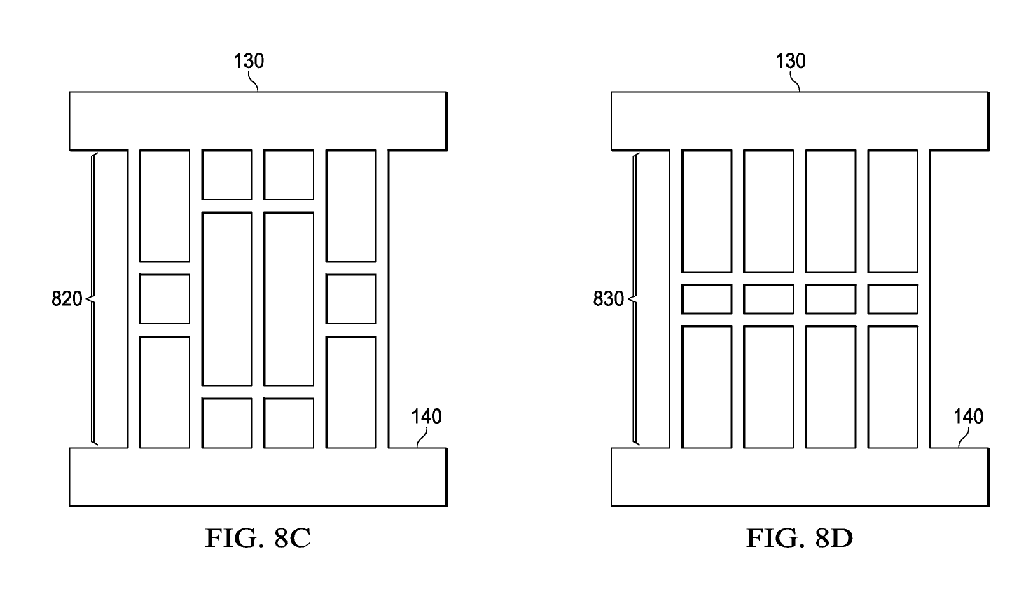

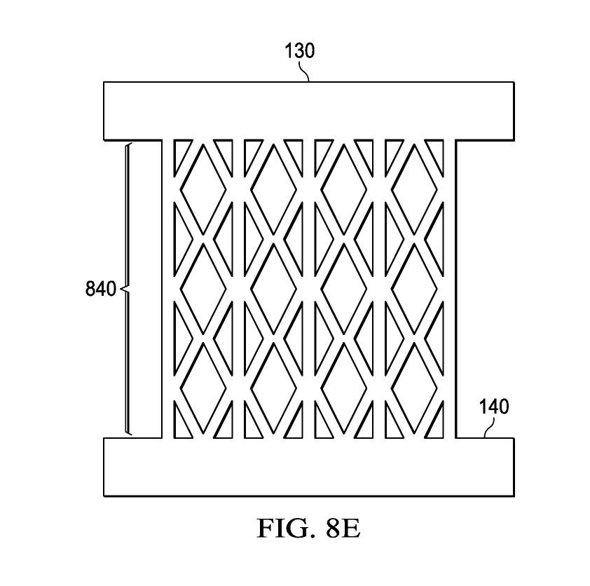

FIGS. 8A-8E illustrates example embodiments of various nanogrid channels;

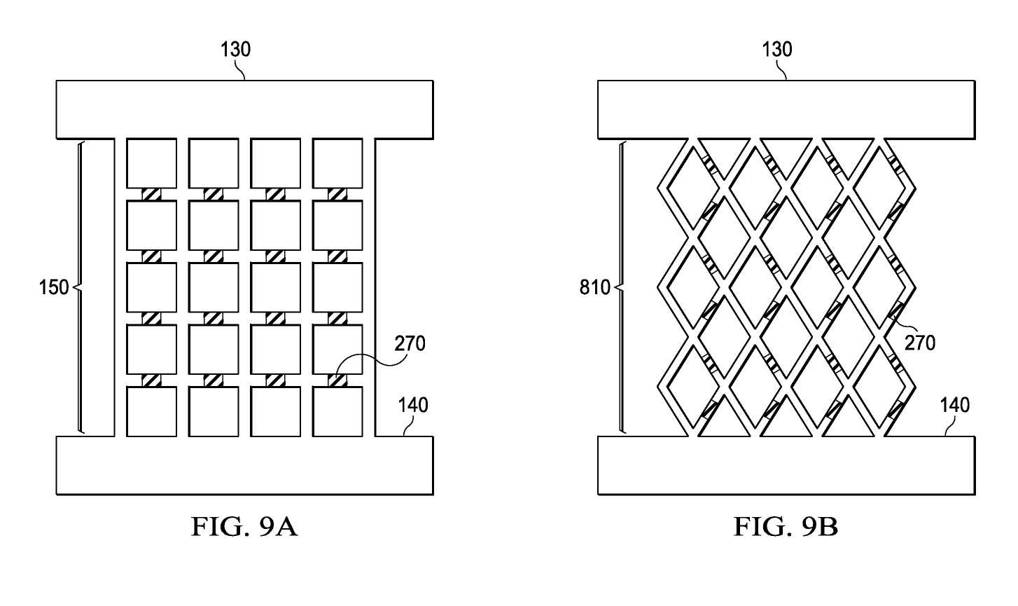

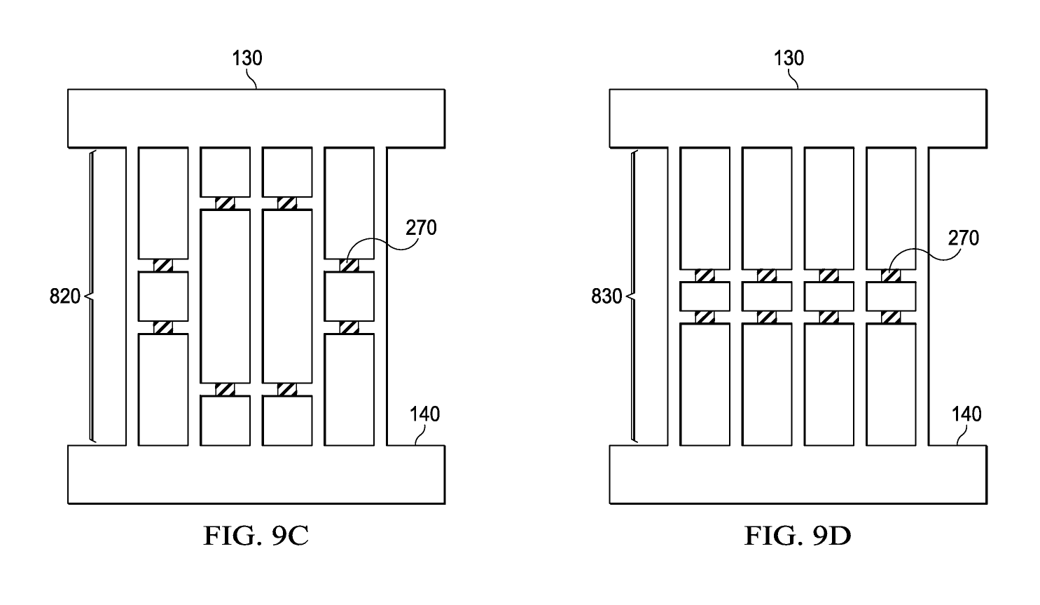

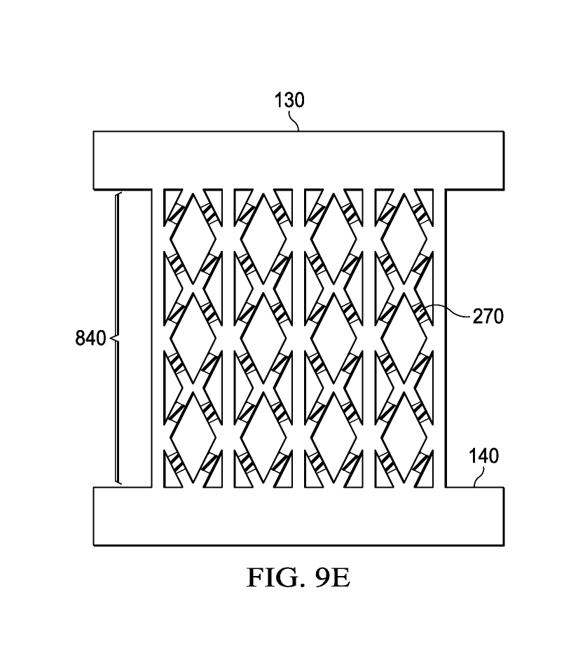

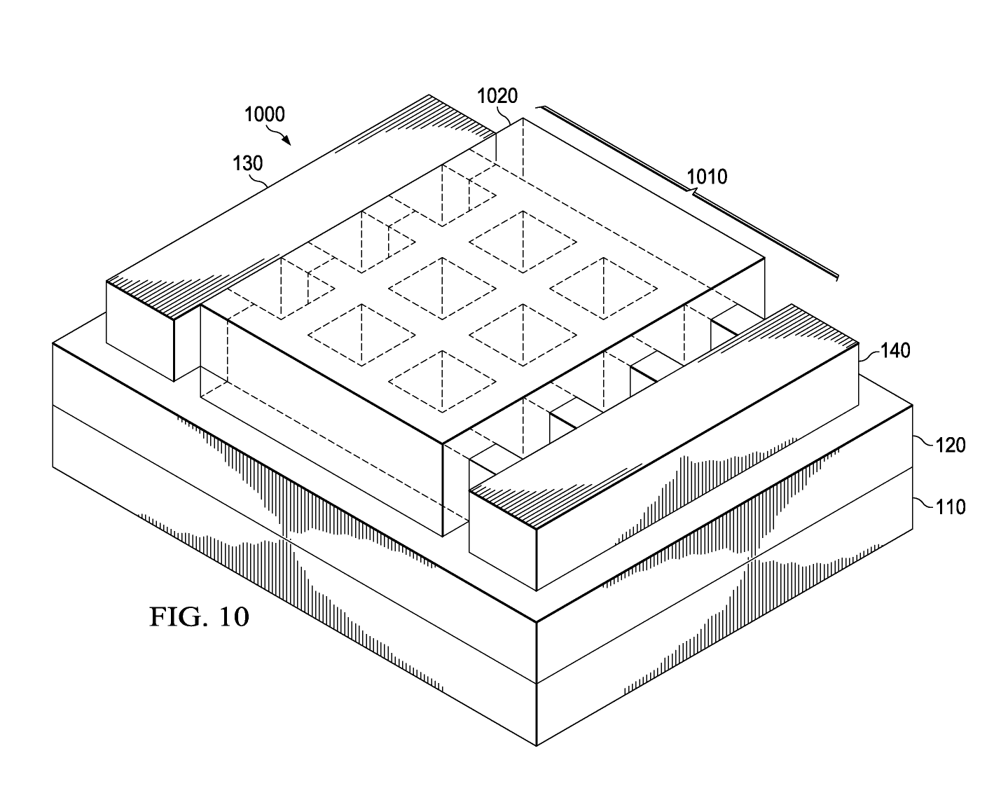

FIGS. 9A-9E illustrates the nanogrid channels of FIGS. 8A-8E, with blocking elements located to configure the electrical equivalent circuit of the nanogrid channels;

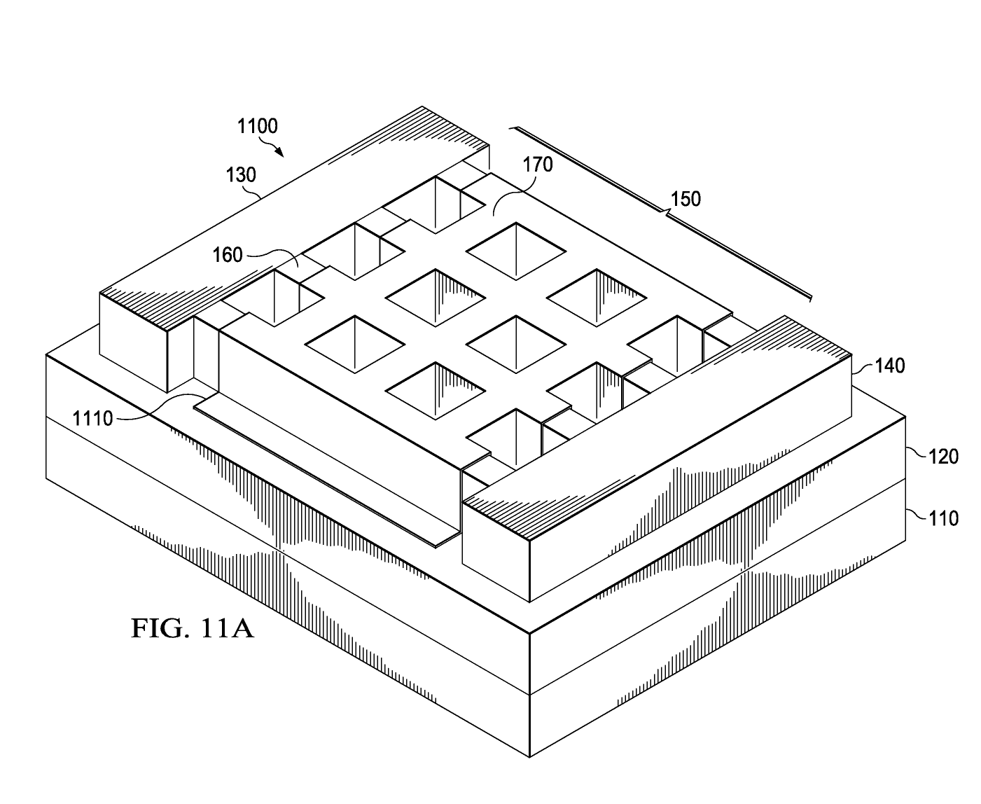

FIG. 10 illustrates an embodiment in which the nanogrid channel of a fin-FET transistor, e.g. the transistor of FIG. 1, is exposed to a sample solution located over the nanogrid channel;

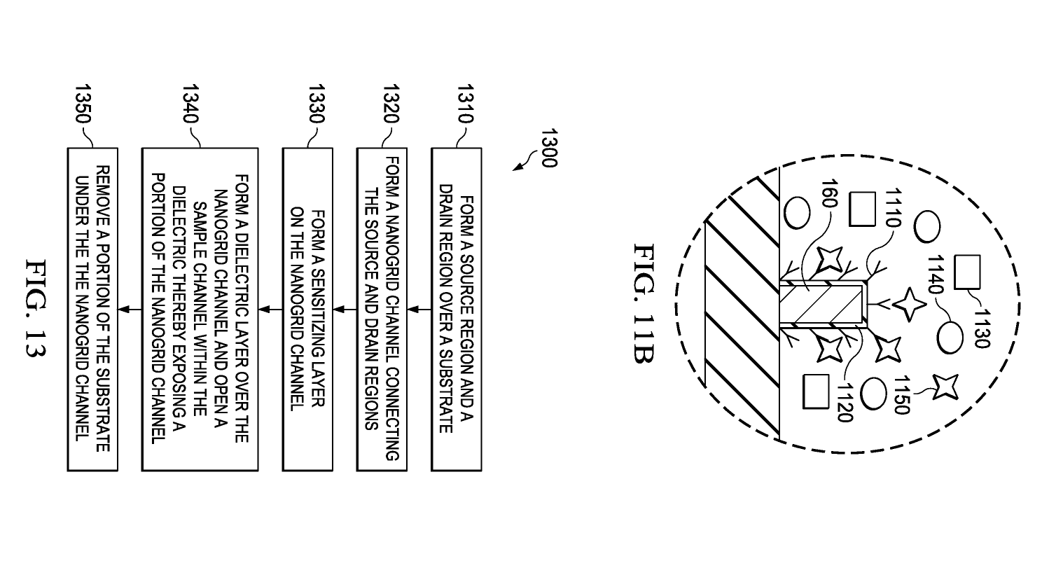

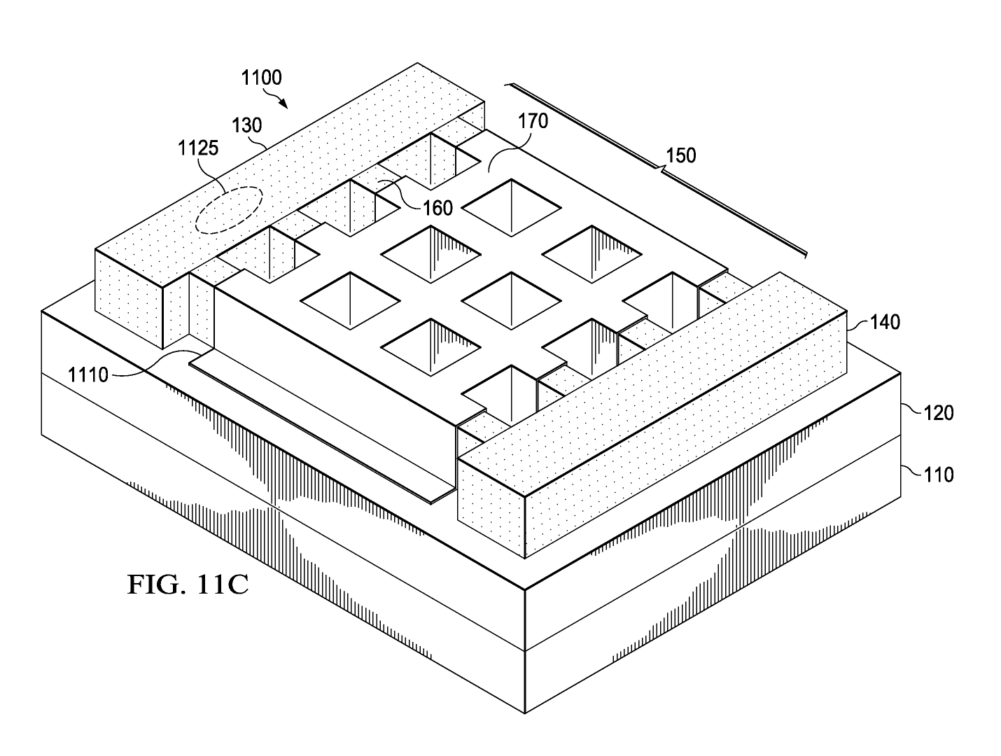

FIGS. 11A-11C illustrate aspects of a an embodiment of the invention, in which the nanogrid transistor includes a binding layer configured to selectively bind to target molecular species;

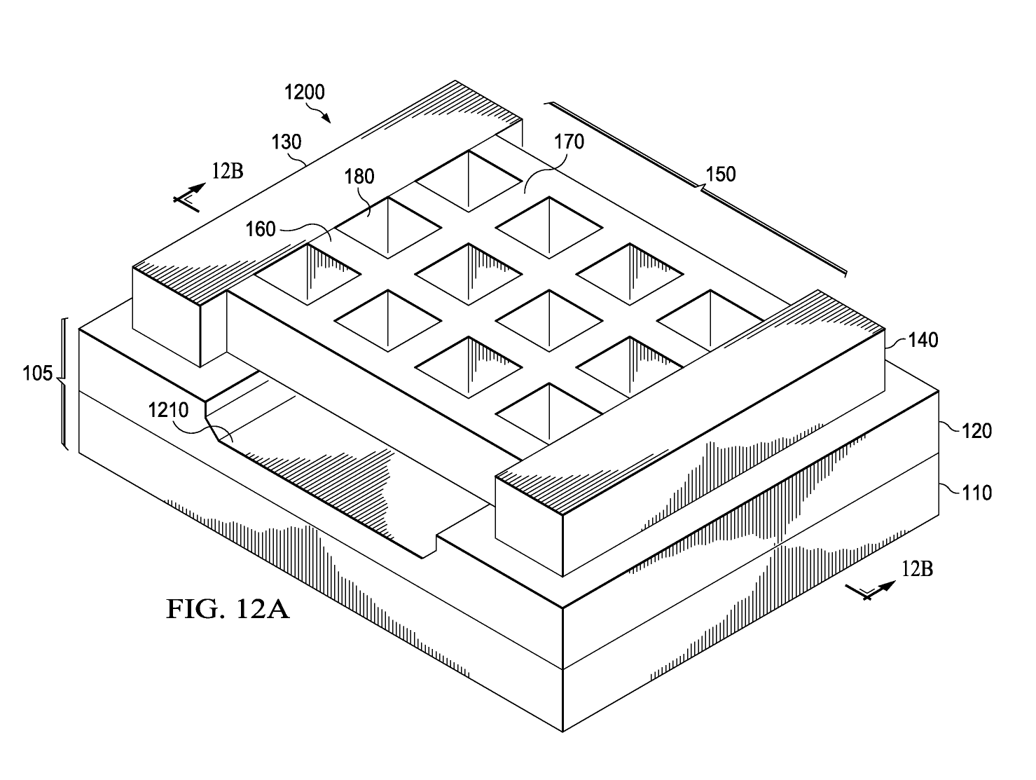

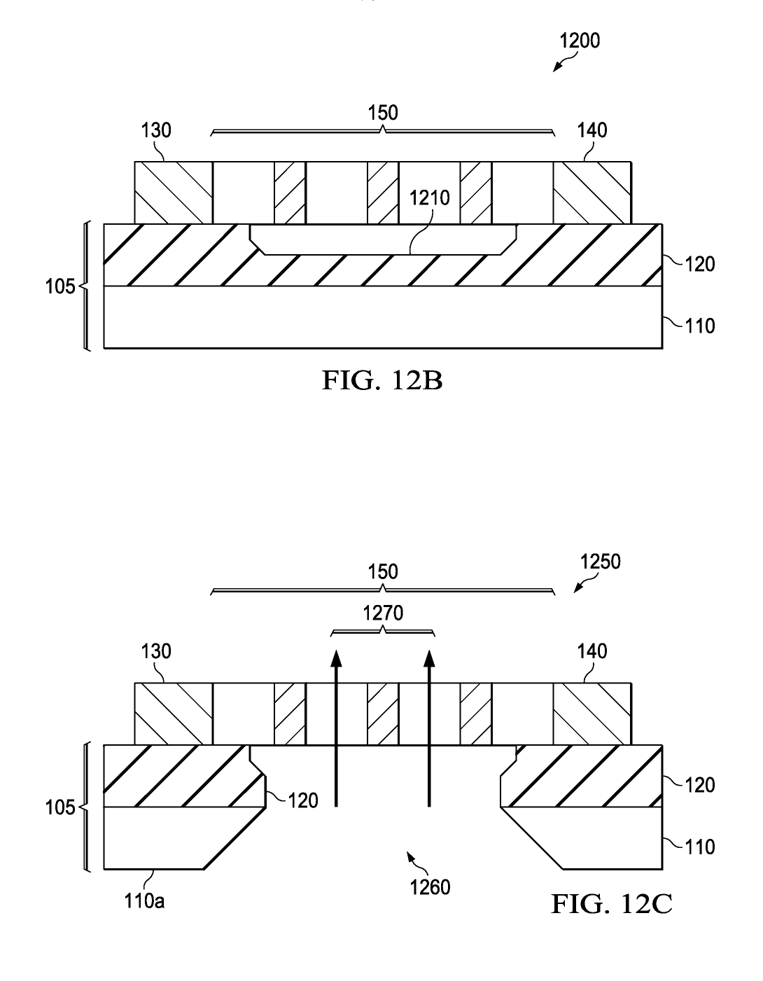

FIGS. 12A-12C illustrate embodiments in which a portion of a substrate, e.g. a bottom oxide, is removed under a nanogrid channel, e.g. any of the nanogrid channels of FIGS. 8A-8E;

FIG. 13 illustrates a method, e.g. for forming the nanogrid fin-FETs of FIGS. 1-12;

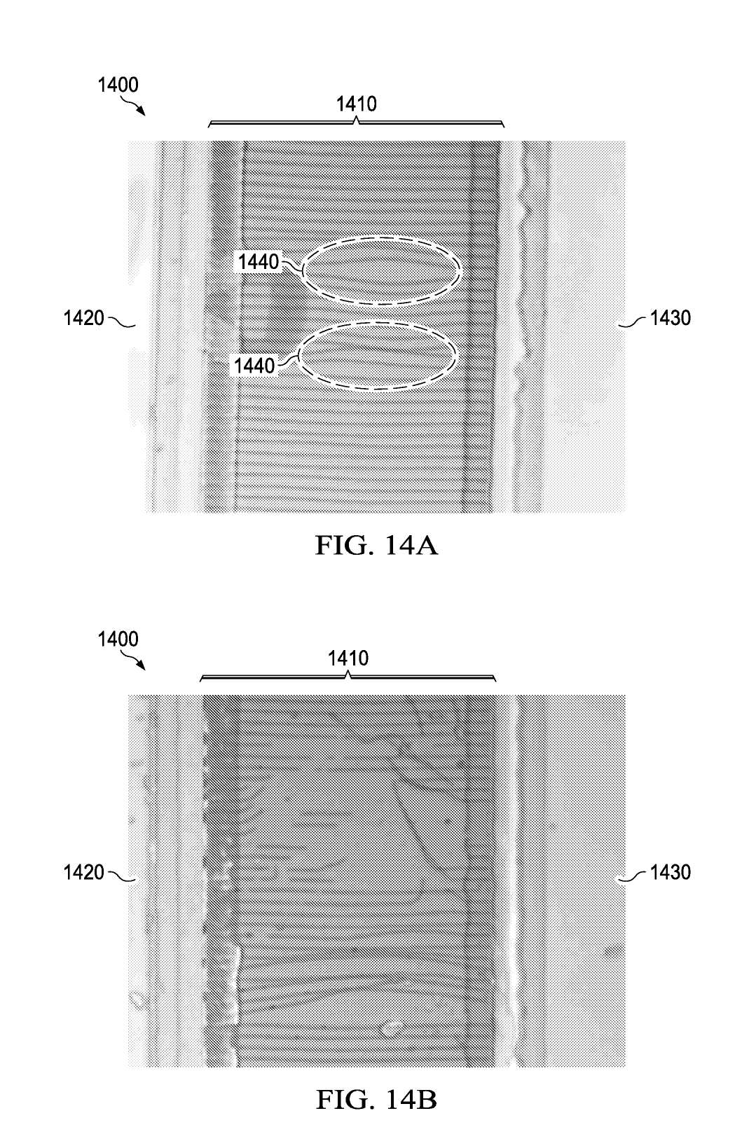

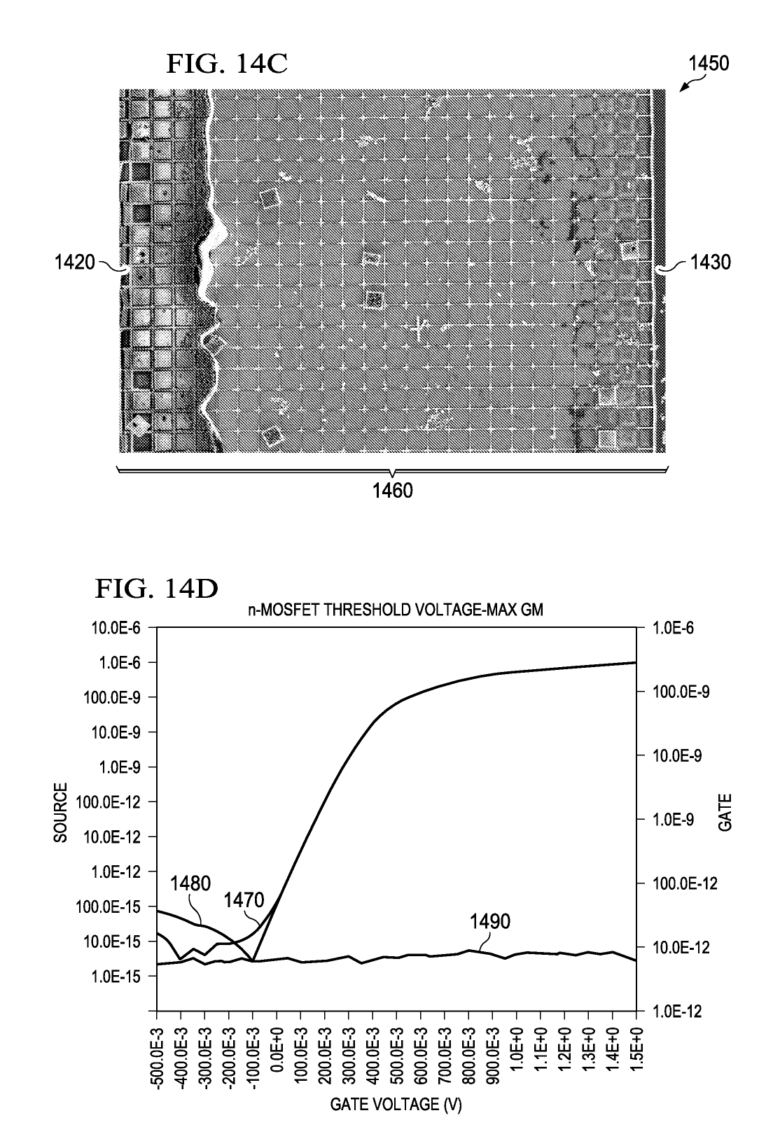

FIGS. 14A-14B illustrate conventional fin channels after removing a portion of an underlying substrate, e.g. a dielectric layer, showing distortion (FIG. 14A) and disintegration (FIG. 14B) of the fin channels;

FIG. 14C illustrates an embodiment of the invention, after removing a portion of a substrate, e.g. a dielectric layer, underlying a nanogrid channel, wherein the nanogrid channel maintains its structural integrity; and

FIG. 14D illustrates current-voltage (IV) curves determined for one nonlimiting embodiment of a nanogrid channel finFET, with and without removal of an underlying dielectric layer, showing essentially no sensitivity of the IV curves to the presence of the underlying dielectric layer.

### DETAILED DESCRIPTION

Planar ISFETs (ion-sensitive field-effect transistors) have been used for electrically based sensing of charged analytes. In some cases the charged analytes, e.g. biomolecules, may cause a large change of transistor channel conductance due to molecules of the analyte binding to that analyte to the gate dielectric of the ISFET. ISFETs typically provide reliable electronic biochemical sensors for real-time measuring pH values of liquid and in-line quality monitoring of milk, beer, yogurt, and the like.

Recently, fin-FETs with multiple nanowidth channels (nanochannels) have been developed which provide a detection limit down to parts per billion (ppb) for gas detection and femtograms per milliliter for detection of target molecules in solution. Some such devices are described, e.g. in PCT Application Publication No. WO 2012/050873 (the “'873 application”), filed on Sep. 28, 2011 and incorporated herein by reference in its entirety. It is believed that the small width of the fin-FET channels, e.g. a “nano width” of about 100 nm or less, confers high sensitivity of the fin-FET to the analyte of interest. This width may be comparable to the Debye length of the semiconductor, e.g. silicon, used to form the nanowidth channels, and comparable to the size of some biomolecules. Thus, when a molecule of interest binds to the channel, the charge on the molecule may in some cases sweep majority charge carriers from a portion of the channel, effectively making the channel nonconductive. In other cases the bound molecule may attract majority charge carriers, thereby increasing the conductivity of the channel.

Sensitivity of a fin-FET biosensor having multiple channels may be improved by increasing the sensor area. Sensor area may be increased by increasing the number of channels or by increasing the length of the channels. However, either of these options may increase the area and/or the cost of the conventional fin-FET sensor. In addition increasing the length of the channels may cause reliability problems due to the fragile nature of nanowidth fins.

Embodiments of the invention described herein are expected to mitigate such deficiencies of conventional fin-FET devices, and to provide advantageous configurability of the fin-FET devices not easily provided by the conventional devices.

Herein and in the claims, a fin-FET is a field-effect transistor having a vertical channel, or “fin” connected between a source region and a drain region. A fin-FET is a type of multi-gate (MuG) FET, or MuGFET. A fin-FET may operate as, e.g., an nMOS or pMOS enhancement mode fin-FET, an nMOS or pMOS depletion mode fin-FET, or an nMOS or pMOS Schottky barrier fin-FET. A multifin-FET is a fin-FET having a plurality of vertical channels connecting the source and drain. A nanogrid fin-FET is a fin-FET having a channel that includes channel segments that form a two-dimensional array, or nanogrid, of channel segments. Such a channel may be referred to as a “nanogrid channel.” The segments of the nanogrid channel have a nano-dimension, e.g. a width of about 100 nm or less. At such dimensions, these segments may be inherently fragile.

When the width of the vertical channel is about equal to or smaller than the Debye length of the channel material, conduction through the vertical channel may be effectively turned off by a charge adjacent the channel, e.g. on a gate electrode or directly on a gate dielectric layer. In sensor applications, this principle is exploited by sensitizing the channel to a target molecular species of interest. Herein the term “molecular species” includes ionic species that may not typically be regarded as molecular, e.g. Na⁺ or Cl⁻. When the molecular species binds to the channel, local charges within the molecule may also reduce conduction through the channel. The reduced conduction may cause a measurable change in the transistor electrical characteristics, indicating the presence of the target molecular species.

Some structures and/or methods described in the '873 application may be suitable for making or using similar structures and/or methods of the present application. FIG. 1 illustrates a nanogrid fin-FET transistor 100 according to one nonlimiting embodiment of the invention. The transistor 100 includes a substrate 105. The substrate includes a handle substrate 110, or simply “handle” 110, and a dielectric layer 120. The handle 110 is not limited to any particular material, but may include, e.g. a semiconductor such as silicon. In some embodiments a silicon wafer provides a convenient handle 110 on which to build the transistor 100, but embodiments are not limited thereto. Without limitation the handle 110 may be referred to herein as a silicon substrate 110, or simply substrate 110, without loss of generality.

The dielectric layer 120 overlies the substrate 110. The dielectric layer 120 is also not limited to any particular material, and in a non-limiting embodiment, may be or include silicon dioxide, also sometimes referred to herein as silicon oxide. In various embodiments it is convenient to provide the substrate 110 and the dielectric layer 120 as a silicon-on-insulator (SOI) wafer. In such embodiments the dielectric layer may be, e.g., silicon dioxide which may be optionally thermally grown on a silicon wafer. Such an oxide layer may be referred to colloquially as a “bottom oxide”, or “BOX” layer. However, embodiments are not limited to a thermally grown oxide layer. For example, in some alternate embodiments the dielectric layer 120 may include another dielectric material, e.g. SiN or SiON, formed over the substrate 110, e.g. a silicon wafer or other suitable substrate, by any suitable method, e.g. plasma deposition.

The transistor 100 includes source and drain regions 130 and 140 that may be, but need not be, conventional. These may be formed from a semiconductor layer, e.g. single crystal silicon, and may be formed from the silicon layer of an SOI wafer. A nanogrid channel 150 is connected physically and electrically between the source and drain regions 130 and 140.

The nanogrid channel 150 includes segments 160 that may run in a direction generally parallel to a direction 165 of net current flow between the source 130 and the drain 140. Semiconductor segments 170 may run in a direction nonparallel to the direction 165 of net current flow, e.g. about normal to the segments 160 in the illustrated embodiment. The segments 170 are illustrated connecting neighboring segments 160, but embodiments are not limited thereto, as discussed further below. In some embodiments, such as the illustrated embodiment, the segments 160 and 170 may form bounded areas 180. These areas are discussed further below.

In some embodiments, the dielectric layer 120 may be a localized insulator beneath the nanogrid channel 150. The localized insulator may be formed by selective oxidation of the bottom portion of the nanogrid channel 150 to isolate the nanogrid channel 150 from the substrate.

The transistor 100 may include a gate electrode (not shown), sometimes referred to as a biasing wire or plate, proximate the nanogrid channel 150 that may include, e.g. a polysilicon or metal electrode. In this context, “proximate” means close or very near. The electrode may be biased to change an operational characteristic, e.g. the conductance, of the nanogrid channel 150. In the case of some sensor applications, the electrode may be used to charge an analyte that binds to the nanogrid channel, which in turn may change the conductance of the nanogrid channel 150. In some embodiments the electrode may be used to bias the transistor 100 into an operational regime that enhances sensitivity to the presence of an analyte. This aspect is discussed further below. Various aspects of some embodiments of the gate electrode are also described further in the '873 application.

FIGS. 11A-11C illustrate embodiments in which a fin-FET transistor 1100 includes a sensor molecule coating. In FIG. 11A, a sensor molecule coating 1110 may be formed on a majority of the nanogrid channel 150. Within this area sensor molecules, which may be or include, e.g. antibodies, aptamers, receptors, DNA, or enzymes, are attached to the gate dielectric of the nanogrid channel. In some cases interface molecules such as an organosilane are first attached to the gate dielectric, and sensor molecules are then attached to the interface molecules.

FIG. 11B shows a sectional view through of one of the segments 160 of the nanogrid channel 150. A gate dielectric 1120 covers the segment 160. The gate dielectric may be, e.g. a thermal oxide produced by a thermal oxidation process. The sensor molecule coating 1110 overlies the gate dielectric 1120. The sensor molecule coating 1110 includes a plurality of sensor molecules that may be configured to preferentially bind to a particular target molecule. In the illustrated embodiment three different target molecules are present, 1130, 1140 and 1150. Target molecules 1130 and 1140 are schematically illustrated as being incompatible with the sensor molecules. The target molecule 1150 is schematically illustrated as being compatible with the sensor molecules. Three instances are shown in which a target molecule 1150 has bound to a corresponding sensor molecule.

The sensor molecule may be attached to the gate dielectric of a fin-FET. When the sensor molecule binds with its target molecule the charge surrounding the channel of the fin-FET transistor may be changed. This change in charge may cause the conductance of the fin-FET transistor channel to change. When the fin-FET biosensor transistor is biased in the subthreshold region, e.g. using a gate electrode or biasing plate, a linear change in the charge from target molecules that are attached to the sensor molecules surrounding the fin-FET nanochannel may cause a logarithmic change in the conductance of the fin-FET nanochannel. Additional details are provided in the '873 application.

In FIG. 11C areas other than the nanogrid channel 150 may be coated with anti-adhesion protective molecules 1125. Anti-adhesion molecules such as polyethylene glycol (PEG) terminated self assembled monolayers (SAMs), benzene terminated SAMs, fluorocarbon silanes, bovine serum albumin (BSA), etc., are expected to substantially prevent target molecules from adsorbing to these surfaces and causing a change in the concentration of target molecules in the sample solution or sample gas. Additional aspects of making and using fin-FET sensors such as the fin-FET transistor 1100 are described in the '873 application.

In various embodiments described herein the nanogrid channel includes a two-dimensional array of channel segments. FIGS. 2A-2C illustrates nonlimiting and nonexclusive aspects of channel segment arrays according to various embodiments.

FIG. 2A illustrates an embodiment of a nanogrid channel, designated nanogrid channel 210a, oriented in an x-y coordinate plane shown for reference without limitation. The nanogrid channel 210a includes semiconducting segments 220-1, 220-2, and semiconducting segments 230-1 and 230-2. The segments 220 may be oriented in the direction of net current flow between the source 130 and the drain 140. The segments 220-1 and 220-2 have a width W and are separated by a space S. The width W may be about 100 μm or less, e.g. a nanowidth. The space S is not limited to any particular value, and in some cases may be substantially larger than 100 nm. The segments 220-1 and 220-2 may be referred to as “nanowires” by virtue of having a width of about 100 nm or less. In the illustrated embodiment the segments 230-1 and 230-2 are oriented parallel to the y-axis of reference coordinate axes. The segments 230-1 and 230-2 may also be nanowires. The segments 230-1 and 230-2 are oriented parallel to the x-axis of the coordinate axes. Thus the segments 220 are oriented about normal to the segments 230. However, as discussed further below, embodiments are not limited to such orthogonal placement of the segments 220 and 230.

In FIG. 2A the segments 230-1 and 230-2 do not connect the segments 220-1 and 220-2. Thus while the segments 220-1 and 220-2 are electrically and mechanically connected at their ends to the source 130 and the drain 140, they are otherwise not connected.

The segments 230-1 and 230-2 may operate in one or more of the following ways. First, these segments may provide mechanical support to the segments 220-1 and 220-2. Second, in embodiments in which the transistor 100 is used as a chemical sensor, the segments 230-1 and 230-2 may modify the interaction between the nanogrid channel 210a and a source of target molecular species, e.g. a solvent such as water. Third, the channel segments 230-1 and 230-2 may modify the electrical response of the nanogrid channel 150 to target molecular species. For example, a target molecule binding to the segment 230-1 may produce an electronic response, e.g. by electronic proximity, that is not typically achievable when the target molecule can only bind directly to the segment 220-1.

FIG. 2B illustrates another embodiment, designated 210b, in which a segment 250 extends from the segment 220-1 to the segment 220-2. Thus the segments 220-1 and 220-2 may be electrically and mechanically connected by the segment 250. It is believed that the segment 250 may mechanically strengthen the segments 220-1 and 220-2, reducing the chance of breaking these segments caused by, e.g. stress or interaction with a fluid potentially bearing target molecular species. It is also believed that multiple instances of the segment 250 may provide multiple conductive paths between the segments 220-1 and 220-2. Thus, for example, the nanogrid channel 150 may behave similarly to a resistor ladder.

FIG. 3 illustrates schematically the nanogrid channel 210b including multiple instances of the segments 220 and 250 such as to form a regular array of resistive elements R. The presence of the segments 220 and 250 increases the surface area of the nanogrid channel 150 available to interact with target molecular species. Moreover it is believed that the array of the segments 220 and 250 may alter the electrical response of the transistor 100 to some target molecular species as compared to a similar multiple-fin fin-FET. Without limitation by theory, the response may be changed by the interaction of the multiple resistive paths of the nanogrid channel 210b, or by making the bounded area 180 small enough to exclude molecules above a particular size. Finally, it is expected that the nanogrid channel 150 will be relatively robust to mechanical stress due to the two-dimensional stabilization of the structure.

FIG. 2C illustrates an embodiment of a nanogrid channel, designated 210c, in which a segment 260 connects two segments 220-1 and 220-2. In this embodiment the segments are arranged as in FIG. 2b. However, the segment 260 includes a blocking element 270 that at least partially reduces conductivity through the segment 260.

FIGS. 4A and 4B illustrate example embodiments of the segment 260 including the blocking element 270. In FIG. 4A the segment 260 includes, e.g. p⁺-doped silicon portions 410. Each of the portions 410 is shown having a resistance R₁. The blocking element 270 is implemented as a high resistance portion 420 with a resistance R₂>>R₁.

In FIG. 4B portions 430 of the segment 260 are doped to one polarity type, e.g. n-type. The blocking element 270 is implemented as a portion 440 doped to the opposite polarity as the portions 430, e.g. p-type. Two p-n junctions 450 at the interfaces between the portion 440 and the portions 430 may operate as two diodes that share a common p-type region. Alternatively, the portions 430 may be p-doped and the portion 440 may be n-doped such that two diodes share a common n-type region. In either case, DC conduction through the segment 260 is substantially prevented.

FIG. 5 illustrates one nonlimiting embodiment of a nanogrid channel designated 510 in which a number of blocking elements 270 are located to produce parallel conductive paths 520a, 520b and 520c through the nanogrid channel 510. The blocking elements 270 substantially prevent conduction between one path 520 and a neighboring path 520. Thus, in the illustrated embodiment it is expected that the nanogrid channel 510 will electrically behave similarly to a multi-fin FET, while benefitting from increased mechanical strength provided by the segments 170. For example, a target molecule may bind to one of the paths 520, causing the resistance due to the remaining paths 520 to increase.

FIG. 6 illustrates another example embodiment in which blocking elements 270 are placed in the nanogrid channel 150 to form a serpentine conductive path 610 from the source 130 to the drain 140. The serpentine path 610 may have particular utility in embodiments in which it is desirable to configure the transistor 100 to be very sensitive to the presence of a low-concentration of the target molecular species. For example, when a target molecule binds to the nanogrid channel 510 anywhere along the conductive path 610 the resistance of the path 610 may increase exponentially with the number of bound target molecules. This resistance change may be reflected in the electrical characteristics of the transistor 100 indicating the concentration of the target molecule. The length of the serpentine path 610 in principle is unlimited, though may be practically limited by desired device size. Thus the transistor 100 configured to include the serpentine path 610 may provide extremely sensitive detection of a target molecular species, while providing improved mechanical stability relative to, e.g. parallel fin-FETs.

The blocking elements 270 may be formed by, e.g., implanting one or more dopant species into nanogrid channel segments at desired locations. Those skilled in the art of semiconductor manufacturing are familiar with such processing, which may include forming photoresist patterns with openings at the desired implant locations. A general nanogrid channel, such as the nanogrid channel 150, may be formed and then configured using the implant process to place the blocking elements 270 at the desired locations. Configuration may include, e.g., forming a serpentine path of a desired length, forming a desired number of parallel conductive paths, or a combination of these aspects. Knowledge of the sensitivity of the nanogrid channel to the binding of the target molecule thereto may guide the designer to determine a conductive path configuration that provides a desired sensitivity of the transistor 100 to the target molecule. The general design of the nanogrid channel may reduce processing costs that might otherwise be required to, e.g. produce different nanogrid channel designs to accommodate different target molecular species.

FIG. 7 illustrates a cross-section of an embodiment of a single nanogrid segment 710 including an undercut 720. The undercut 720 may be produced as an artifact of some processes used to form the nanogrid segment 710. In conventional multi-fin finFETs the absence of cross members, e.g. the segments 230 or 250, may leave the fins vulnerable to delamination and damage due to weakening caused by the undercut 720. The segments 230 or 250 are expected to significantly stabilize the nanogrid segment 710, thereby reducing the risk of delamination of the nanogrid segments 720. This aspect is discussed further below.

FIGS. 8A-8E illustrate nonlimiting examples of various different nanogrid channel designs. These example embodiments illustrate various aspects of the nanogrid channel 150 that may be varied according to the requirements of a particular application. FIG. 8A illustrates again the nanogrid channel for reference as an example of nanogrid segments arranged in an x-y grid pattern with regular spacing between the segments. FIG. 8B illustrates an embodiment of a nanogrid channel 810 in which segments may have an acute or obtuse angle with respect to each other such that a “diamond” grid is formed. FIGS. 8C and 8D respectively show examples of nanogrid channel 820 and 830 that include orthogonal nanogrid segments. In these two examples the nanogrid segments form bounded areas of different sizes and relationships. FIG. 8E shows an example nanogrid 840 that combines aspects of a multi-fin FET and the acute-obtuse segments of the nanogrid channel 810.

The two-dimensional grids of each of the nanogrid channels 150 and 810-840 are expected to provide superior mechanical stability relative to conventional multi-fin FET devices. Moreover, the different configurations of bounded areas illustrated by these nanogrids are expected in some cases to provide different sensitivity to various target molecules, due to, e.g. viscosity and/or molecular size exclusion. Such differences may affect the sensitivity to target molecules of nanogrids with different configurations of bounded areas. This aspect may provide a designer with another design variable to determine the sensitivity of the transistor 100 to various target molecules.

FIGS. 9A-9E illustrates the same nanogrid configurations as shown in FIGS. 8A-8E. However the nanogrids of FIGS. 9A-9E include multiple instances of the blocking elements 270 configured to provide one or more conductive paths between the source 130 and the drain 140. The blocking elements 270 may be located to produce one or more conductive paths through the illustrated nanogrids to produce transistors 100 of varying sensitivity to target molecules. The factors of grid size, segment length and orientation, and placement of blocking elements are expected to provide an effective suite of design variables to customize the design of the transistor 100 to achieve a desired sensitivity of the transistor 100 to various target molecules. Moreover, the performance of the transistor 100 may be tailored to use with various liquids with different viscosities, such as, e.g., water, blood, urine, and milk.

FIG. 10 illustrates an embodiment of a fin-FET transistor 1000 in which a nanogrid channel 1010 is exposed to a sample solution 1020. The sample solution 1020 may include one or more solutes to which the nanogrid channel 1010 has been configured to respond. As described below the nanogrid channel 1010 may be sensitized to the presence of the solute(s). The electrical properties of the transistor 1000 may change in response to the presence of the solute(s). The nanogrid channel 1010 may include mutually orthogonal segments, or segments that form acute or obtuse angles with respect to each other. The nanogrid channel 1010 may include placements of the blocking elements 270 to form one or more conductive paths between the source 130 and the drain 140. The nanogrid channel 1010 may thereby impart on the transistor 1000 various operational characteristics that may be beneficial in various target applications.

FIGS. 12A and 12B respectively show an oblique projection and a section of a fin-FET transistor 1200 according to another embodiment of the invention. In the illustrated embodiment a portion is removed of a substrate 105 that includes the handle substrate 110 and the dielectric layer 120. In the illustrated embodiment the removed portion forms a recess 1210 in the dielectric layer 120 under the nanogrid channel 150. In such embodiments the nanogrid channel 150 may be described as “floating”. The recess 1210 may be formed in the dielectric layer 120, e.g. silicon oxide, before locating thereover the semiconductor layer from which the source 130, drain 140, and nanogrid channel 150 are formed. The recess 1210 may be filled with a selectively removable material, e.g. silicon nitride, and planarized. The nanogrid channel 150 may be formed over the filled nanogrid channel, and then the selectively removable material may be removed to allow the flow of a sample solution (not shown) under the nanogrid channel 150. In this manner the sample solution may interact with the nanogrid channel 150 on all sides.

The exposed underside of the nanogrid channel 150 may increase sensitivity of the transistor 1200 to target molecules of interest. Some embodiments of the biosensor 1200 may also include the recess 1210 thereby increasing sample fluid contact with the underside of the nanogrid channel 150.

FIG. 12C illustrates an embodiment, e.g. a finFET sensor 1250, in which a portion of the substrate 105, e.g. the dielectric layer 120, is removed resulting in an opening 1260 from a backside 110a of the handle substrate 110. The opening 1260 may be formed using conventional techniques that may include plasma etch and/or wet chemical etch techniques. The sensor 1250 may be configured such that a sample fluid may flow vertically (in the plane of the figure) as indicated for example by flow 1270. On some cases the vertical flow provided by the sensor 1250 may be more easily configured or accommodated in a sensor system design, easing constraints a sensor system design. It is expected that the vertical flow may significantly reduce the detection time of the sensor 1250 because the target molecules in the solution only need to diffuse a short distance from the bounded areas 180 to the surface of the nanogrid 150, e.g. local diffusion. It is thought that local diffusion of target molecule may be highly desirable for biosensors, and some embodiments of the nanogrid finFET described herein, e.g. the sensor 1250, provide the necessary mechanically stable sensing elements for enabling local diffusion, while conventional fin-FETs typically cannot.

FIGS. 14A-14D illustrate aspects of fabricated sample devices that illustrate aspects of the invention without limitation. FIGS. 14A and 14B present micrographs that illustrate a finFET sensor 1400 that includes a fin channel 1410 connecting a source 1420 and a drain 1430. The fin channel 1410 lacks cross members such as the segment 250. The sensor 1400 includes a recess formed under the channel 1410, such as the recess 1210.

FIG. 14A shows the sensor 1400 after fabrication but before exposure to a fluid such as liquid sample including target molecules. In this figure, distorted fins 1440 are evident. It is thought that these distortions are caused by residual stress in the floating fins of the channel 1410. FIG. 14B illustrates the sensor 1400 after exposing the fin channel 1410 to a liquid, e.g. an aqueous solution. It is immediately apparent that many fins of the fin channel 1410 have been fractured and/or displaced. This figure clearly illustrates that at least for the illustrated example the fin channel 1410 formed without cross members is too weak mechanically to survive exposure to a sample liquid such as water when the dielectric layer 120 is removed under the fin channel 1410.

FIG. 14C illustrates a sensor 1450 that includes a nanogrid channel 1460 that includes cross members, e.g. segments 250. In this embodiment a portion of the dielectric 210 underlying the nanogrid channel 1460 again has been removed so that the nanogrid channel 1460 is floating. In this embodiment the nanogrid channel 1460 apparently exhibits excellent mechanical stability, e.g. no apparent distortion, as compared to the fin channel 1410. Thus, this embodiment clearly illustrates at least one aspect for which the nanogrid channel confers an advantage relative to conventional fin channel FET sensors.

FIG. 14D illustrates current-voltage (I-V) characteristics of one embodiment of a nanogrid channel, e.g. the nanogrid channel 150, with the oxide underlying the nanogrid channel present (1470) and with the oxide removed (1480). Above a gate voltage of about 0 V, the characteristics 1470 and 1480 are essentially indistinguishable. This aspect is believed to indicate that removing the dielectric under the nanogrid channel has little effect on relevant electrical performance of a FET sensor using the nanogrid channel. A characteristic 1490 indicates that the leakage current is low for embodiments such as that illustrated by the sensor 1450, thus providing a high sensitivity of the detected electrical response to target molecules in a sample solution.

It is expressly recognized that scope of the description and the claims includes embodiments of finFET transistors that are configured other than as sensors. The use of various features described herein, e.g. the segments 250, may significantly improve mechanical strength of a multi-fin channel, thereby reducing fin breakage during subsequent processing significantly improving manufacturing yield. Some such embodiments may include blocking elements, such as the blocking elements 270, to configure one or more conductive paths through the multi-fin channel.

Turning to FIG. 13 a method 1300 for forming a fin-FET transistor, e.g. a sensor, is illustrated in one embodiment of the invention. The steps of the method 1300 are described without limitation by reference to elements previously described herein, e.g. in FIGS. 1-13. The steps of the method 1300 may be performed in another order than the illustrated order, and in some embodiments may be omitted altogether and/or performed concurrently or in parallel groups.

In a step 1310, a source region, e.g. the source 130, and a drain region, e.g. the drain 140, are formed over a substrate. In a step 1320 a nanogrid channel, e.g. the nanogrid channel 150, is formed that connects the source and drain regions. The nanogrid channel connects the source and drain regions, and includes first and second vertical channel regions, e.g. the semiconductor segments 220-1 and 220-2, and a space between the first and second vertical channel regions, e.g. the space S (FIG. 2A). A cross member, e.g. the segment 250, extends from the first vertical channel region into the space.

In any embodiment of the method the cross member may physically connect the first and second vertical channel regions. In some such embodiments the cross member may include a low conductivity region that reduces conduction between the first and second vertical channel regions. In some other embodiments the cross member may include two PN junctions that share a common doped region, thereby substantially preventing conduction between the first and second vertical channel regions.

In any of the above-described embodiments of the method, a portion of a dielectric layer underlying the nanogrid channel may be removed, such that the nanogrid channel is floating.

Any embodiment of the method may include an additional step 1330 for forming a sensitizing layer on the nanogrid channel. The sensitizing layer when present is configured to interact with a target molecular species in contact with the nanogrid channel. The interaction may change an electrical parameter of the transistor.

Some of the above-described embodiments of the method may include an additional step 1340 in which a dielectric layer is formed over the nanogrid channel, and a sample channel is located within the dielectric thereby exposing a portion of the nanogrid channel.

Some embodiments may include a step 1350 in which a portion of the substrate is removed, e.g. as exemplified by the recess 1210 or the opening 1260. In any of the above-described embodiments the nanogrid channel may be formed over a silicon-on-insulator substrate.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above-described embodiments. Rather, the scope of the invention should be defined in accordance with the following claims and their equivalents.

What is claimed is:

1. A transistor, comprising:
a source region and a drain region located over a substrate; and
a nanogrid channel connecting said source and drain regions, said nanogrid channel including:
first and second vertical channel regions connecting said source and drain regions and having a space therebetween; and
a cross member that extends from said first vertical channel region into said space.

2. The transistor of claim 1, wherein said cross member physically connects said first and second vertical channel regions.

3. The transistor of claim 2, wherein said cross member includes a low conductivity region that reduces conduction between said first and second vertical channel regions.

4. The transistor of claim 2, wherein said cross member includes two PN junctions that share a common doped region, thereby substantially preventing conduction between said first and second vertical channel regions.

5. The transistor of claim 1, further comprising a dielectric layer underlying said first and second vertical channel regions, wherein said dielectric layer is removed from under a portion of said first and second channel regions.

6. The transistor of claim 1, further comprising a biasing electrode proximate said nanogrid channel configured to control an operating characteristic of said nanogrid channel.

7. The transistor of claim 1, further comprising a sensitizing layer located on said nanogrid channel, said layer being configured to interact with a target species in contact with said nanogrid channel thereby changing an electrical parameter of said transistor.

8. The transistor of claim 1, further comprising:
a dielectric overlying said nanogrid channel; and
a sample channel located within said dielectric and exposing a portion of said nanogrid channel.

9. The transistor of claim 1, wherein said nanogrid channel is formed over a silicon-on-insulator (SOI) substrate.

10. The transistor of claim 1, further comprising a recess in said substrate under said nanogrid channel.

11. The transistor of claim 10, wherein said recess extends through said substrate to a backside surface thereof.

12. A method of forming a transistor, comprising:
forming a source region and a drain region over a substrate; and
forming a nanogrid channel connecting said source and drain regions, said nanogrid channel including:
first and second vertical channel regions connecting said source and drain regions and having a space therebetween; and
a cross member that extends from said first vertical channel region into said space.

13. The method of claim 12, wherein said cross member physically connects said first and second vertical channel regions.

14. The method of claim 13, wherein said cross member includes a low conductivity region that reduces conduction between said first and second vertical channel regions.

15. The method of claim 13, wherein said cross member includes two PN junctions that share a common doped region, thereby substantially preventing conduction between said first and second vertical channel regions.

16. The method of claim 12, wherein a dielectric layer underlies said first and second vertical channel regions, and a portion of said dielectric layer is removed from under a portion of said first and second channel regions

17. The method of claim 12 further comprising forming a gate electrode proximate said nanogrid channel configured to configured to control an operating characteristic of said nanogrid channel.

18. The method of claim 12, further comprising forming a sensitizing layer on said nanogrid channel, said layer being configured to interact with a target species in contact with said nanogrid channel thereby changing an electrical parameter of said transistor.

19. The method of claim 12, further comprising:
forming a dielectric layer over said nanogrid channel; and
opening a sample channel within said dielectric thereby exposing a portion of said nanogrid channel.

20. The method of claim 12, wherein said nanogrid channel is formed over a silicon-on-insulator (SOI) substrate.

21. The method of claim 12, further comprising removing a portion of said substrate under said nanogrid channel, thereby exposing an underside of said nanogrid.

22. The method of claim 21, wherein said removing includes forming a passage that extends through said substrate to a backside surface thereof.
